(19) United States
(12) Patent Application Publication
(10) Pub. No.: US 2022/0174832 A1
(43) Pub. Date: Jun. 2, 2022

(54) FLEXIBLE COMPOSITE COVER WINDOW, MANUFACTURING METHOD THEREOF, AND DISPLAY DEVICE USING THE SAME

(71) Applicant: Solip Tech Co., Ltd., Daejeon (KR)

(72) Inventor: Ji Hoon KO, Deajeon (KR)

(21) Appl. No.: 17/494,425

(22) Filed: Oct. 5, 2021

(30) Foreign Application Priority Data
Nov. 27, 2020 (KR) 10-2020-0161935

(51) Int. Cl. H05K 5/03; B32B 17/06; B32B 5/02; B32B 7/023; B32B 7/12; B32B 37/12; B32B 17/04

(52) U.S. Cl. CPC H05K 5/03; B32B 2457/20; B32B 5/02; B32B 7/023; B32B 7/12; B32B 37/12; B32B 17/04; B32B 2307/412; B32B 2262/101; B32B 2260/021; B32B 2260/046; B32B 2307/732; B32B 2315/08; B32B 2315/085; B32B 2255/26; B32B 2307/418; B32B 17/067

(57) ABSTRACT

Proposed is a flexible composite cover window including a transparent glass-fabric reinforced plastic film that adheres to a rear surface or a front surface of the glass, in order to improve the pen-drop impact resistance of a glass cover window used in a flexible display. An effect of the embodiment is to provide a flexible cover window in which the glass-fabric reinforced plastic film protects the glass against impact applied to the glass or offsets the impact such that the pen-drop impact resistance is improved and strength and flexibility are secured.

### BACKGROUND OF THE INVENTION

### Field of the Invention

The present invention relates to a flexible composite cover window and a manufacturing method thereof, and more specifically, to a flexible composite cover window and a manufacturing method of the flexible composite cover window of which impact resistance is improved by causing a transparent glass-fabric reinforced plastic film to adhere to glass.

### Description of the Related Art

The development of the IT industry resulted in a focus shift to convenient mobility of an information terminal, and thus a lot of studies on a technology for miniaturizing and weight-lightening the terminal are conducted. Meanwhile, as an amount of information increases, there is a demand for enlargement of a display which delivers information through the information terminal, rather than miniaturization thereof, and thus a lot of studies for development of a technology for the enlargement of a display are also conducted.

In order to meet both of the two conflicting demands, a flexible display technology having advantages of both convenient portability and enlargement of a screen attracted attention as the next generation technology. Currently, the flexible display is applied to various display fields of smart phone, tablet PC, navigation, electronic book, laptop, and the like.

In general, the flexible display needs to include a cover window at an outer covering of the flexible display for protecting the inside of the display and for the touching of a user. A cover window according to the related art is often made of transparent glass having high strength and hardness. However, a cover window for a flexible display is to have reliable flexibility so as to be foldable or bendable, and no mark is allowed at the cover window even with repetitive folding and bending, and no distortion thereof due to the repetitive folding and bending is allowed. In this respect, glass can be easily broken when being folded or bent, and thus a problem arises in that it is difficult to apply the glass to the flexible display.

In order to solve the problem, a cover window of a flexible display has a plastic film such as a PI film or a PET film at a surface of a display panel. However, the plastic film has problems of low mechanical strength and surface hardness, a mark remaining at a folded and bent part, and a possibility of breakage due to repetitive folding and bending.

In order to solve the above-described problems of the related art, a lot of studies on a glass-based cover window are conducted. Korean Unexamined Patent Publication Nos. 10-2018-0063940 and 10-2019-0018114 provide a flexible glass cover window that has a small thickness and can be bent with low curvature. When this glass-based cover window is folded or bent, the glass-based cover window needs to have no distortion at a display screen and have a basic physical property of sufficient strength so as to endure external pressure and impact such as repetitive touch of a touch pen or the like. In order for glass to be folded or bent, the glass has to have a thickness equal to or smaller than a certain thickness, while having to have a thickness equal to or larger than a certain thickness in order to increase strength. In order to supplement the thin flexible glass cover window, Korean Unexamined Patent Publication Nos. 10-2017-0122554 and 10-2018-0036304 and Korean Patent Registration No. 10-2068685 provide a glass cover window that satisfies both strength and folding characteristics by dividing a region such that a folded region has a small thickness and the other region has a large thickness. However, a thickness step of the other region can become visible, a part of the step can be vulnerable, and manufacturing costs thereof increases. Thus, the glass cover window is difficult to use. Hence, a technology for providing a cover window having appropriate flexibility and strength, while having a uniform thickness, needs to be provided.

### CITATION LIST

### Patent Literature

Patent Literature 1: Korean Unexamined Patent Publication No. 10-2018-0063940

Patent Literature 2: Korean Unexamined Patent Publication No. 10-2019-0018114

Patent Literature 3: Korean Unexamined Patent Publication No. 10-2017-0122554

Patent Literature 4: Korean Unexamined Patent Publication No. 10-2018-0036304

Patent Literature 5: Korean Patent Registration No. 10-2068685

### SUMMARY OF THE INVENTION

A technical object to be achieved by the invention is to solve the above-described problems of the related art and provide a flexible composite cover window, a manufacturing method thereof, and a display device using the same, the flexible composite cover window including a transparent glass-fabric reinforced plastic film that is bonded to the glass so as to have high strength and good folding and bending characteristics.

Technical objects to be achieved by the invention are not limited to the technical object mentioned above, and the following description enables other unmentioned technical objects to be clearly understood by a person of ordinary skill in the art to which the invention pertains.

In order to achieve the technical object, an embodiment of the invention provides a flexible composite cover window.

According to the embodiment of the invention, a flexible composite cover window 100 includes: glass 110; and a transparent glass-fabric reinforced plastic film 120 positioned on the glass.

The transparent glass-fabric reinforced plastic film 120 may be bonded to a front surface, a rear surface, or both the front surface and the rear surface of the glass 110.

Here, the glass 110 and the transparent glass-fabric reinforced plastic film 120 may have a thickness of 0.1 mm or smaller such that each of the glass and the transparent glass-fabric reinforced plastic film is independently foldable or bendable.

An Example of transparent plastic resin used in the transparent glass-fabric reinforced plastic film 120 may include any one selected from the group consisting of siloxane resin, silicone resin, acrylic resin, epoxy resin, styrene-based resin, styrene-acrylonitrile resin, polycarbonate-based resin, polyester resin, polyurethane-based resin, acrylonitrile-butadiene-styrene-based resin, and a compound thereof.

Here, a difference in refractive index between the glass fabric and the transparent plastic resin may be 0.05 or lower.

Here, the transparent glass-fabric reinforced plastic film 120 may have optical transmittance of 80% or higher.

Here, the flexible composite cover window may further include an adhesive layer or a coating layer positioned between the glass and the transparent glass-fabric reinforced plastic film.

Here, the flexible composite cover window may further include a hard coating layer positioned on the front surface of the glass.

In order to achieve the technical object, another embodiment of the invention provides a manufacturing method of a flexible composite cover window.

In the other embodiment of the invention, the manufacturing method of a flexible composite cover window includes: preparing glass; and forming a transparent glass-fabric reinforced plastic film on the prepared glass.

In the forming of the transparent glass-fabric reinforced plastic film on the glass, the transparent glass-fabric reinforced plastic film may be formed by adhering to the glass by using an adhesive.

Alternatively, in the forming of the transparent glass-fabric reinforced plastic film on the glass, in order to avoid using an adhesive having a soft property, the transparent glass-fabric reinforced plastic film may adhere to the glass by putting glass fabric on the glass, applying transparent plastic resin thereon, then, directly impregnating the glass fabric with the transparent plastic resin, and press-hardening the transparent plastic resin.

In order to achieve the technical object, still another embodiment of the invention provides a display device.

According to the embodiment of the invention, the display device includes: the flexible composite cover window according to the embodiment of the invention.

### BRIEF DESCRIPTION OF THE DRAWINGS

FIG. 1 is a schematic view illustrating a schematic cross-section of a flexible composite cover window including a transparent glass-fabric reinforced plastic film which is bonded to a front surface of glass, according to an embodiment of the invention;

FIG. 2 is a schematic view illustrating a schematic cross-section of a flexible composite cover window including transparent glass-fabric reinforced plastic films which are bonded to both front and rear surfaces of glass, according to another embodiment of the invention; and

FIG. 3 is a schematic view illustrating a schematic cross-section of the flexible composite cover window including the transparent glass-fabric reinforced plastic film 120, which is bonded to a rear surface of the glass, and further including a hard coating layer on the front surface of the glass, according to the embodiment of the invention.

### DETAILED DESCRIPTION OF THE PREFERRED EMBODIMENTS

Hereinafter, the invention is to be described with reference to the accompanying drawings. However, the invention can be embodied in various different examples and thus is not limited to embodiments described here. Besides, a part unrelated to the description is omitted from the drawings in order to clearly describe the invention, and similar reference signs are assigned to similar parts through the entire specification.

In the entire specification, a case where a certain part is “connected to (attached to, in contact with, or coupled to)” another part means not only a case where the parts are “directly connected” to each other, but also a case where the parts are “indirectly connected” to each other with another member interposed therebetween. In addition, a case where a certain part “comprises” a certain configurational element does not mean that another configurational element is excluded but means that the other configurational element can be further included, unless specifically described otherwise.

Terms used in this specification are only used to describe a specific embodiment and are not intentionally used to limit the invention thereto. A singular form of a noun includes a plural meaning of the noun unless obviously implied otherwise in context. In this specification, words such as “to comprise” or “to include” are to be understood to specify that a feature, a number, a step, an operation, a configurational element, a member, or a combination thereof described in the specification is present and not to exclude a possibility of presence or addition of one or more other features, numbers, steps, operations, configurational elements, members, or combinations thereof in advance.

Hereinafter, embodiments of the invention are to be described in detail with reference to the accompanying drawings.

A flexible composite cover window according to an embodiment of the invention is described.

FIG. 1 is a schematic view illustrating a schematic cross-section of a flexible composite cover window including a transparent glass-fabric reinforced plastic film that is bonded to a front surface of glass, according to the embodiment of the invention.

With reference to FIG. 1, a flexible composite cover window 100 according to the embodiment of the invention includes: glass 110; and a transparent glass-fabric reinforced plastic film 120 positioned on the glass.

The transparent glass-fabric reinforced plastic film 120 can be bonded to a front surface, a rear surface, or both the front surface and the rear surface of the glass 110.

Here, the glass 110 and the transparent glass-fabric reinforced plastic film 120 can have a thickness of 0.1 mm or smaller such that each of the glass and the transparent glass-fabric reinforced plastic film is independently foldable or bendable.

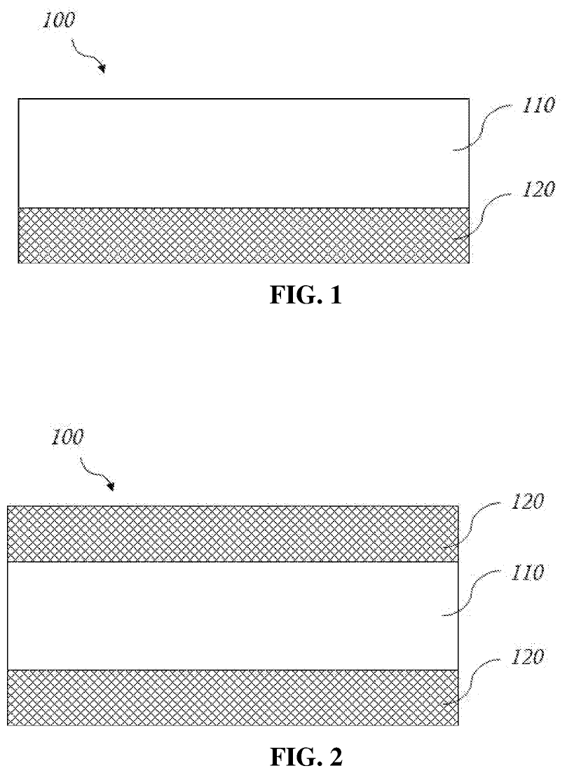

FIG. 2 is a schematic view illustrating a schematic cross-section of a flexible composite cover window including transparent glass-fabric reinforced plastic films that are bonded to both front and rear surfaces of glass, according to another embodiment of the invention.

With reference to FIG. 2, the flexible composite cover window of the invention can include the transparent glass-fabric reinforced plastic film 120 which is bonded to both the front surface and the rear surface of the glass 110.

In general, when impact is applied to glass, a front surface of the glass is subjected to compression due to the impact, and a rear surface of the glass opposite thereto is subjected to tension. In other words, when a pen-drop impact is applied to the glass, the impact is applied as the compression to the front surface of the glass, is transmitted into the glass, and is applied as tension to the other surface of the glass such that the glass is broken due to impact deformation. The thinner the glass and the softer an adhering portion, the more the tension applied to the rear surface of the glass increases. Thus, the glass is broken. Hence, the glass is broken due to the tension applied to the rear surface rather than the compression applied to the front surface. Hence, when a flexible cover window which is foldable or bendable is to be embodied using glass, the glass has to have a certain strength characteristic while having a small thickness to be folded or bent. Hence, when a coating or a film having high strength and a high elastic modulus is bonded to reduce deformation of the front surface or the rear surface of the glass due to impact in order to increase the strength while the thickness of the glass does not increase, and thereby the tension and the impact deformation which are to be applied to the rear surface of the glass is reduced using the coating and the film as a solid impact absorbing support layer, breakage of the glass is inhibited such that the impact resistance can be improved.

In the invention, the transparent glass-fabric reinforced plastic film 120 that has high strength and can improve cushioning of impact is used as the solid impact absorbing support layer.

The transparent glass-fabric reinforced plastic film 120 of the invention is a film containing glass fabrics in a transparent plastic substrate and is a composite film having strength and an elastic modulus higher than those of a general plastic film, by having the inside of the plastic film reinforced with glass fabrics as described above. The transparent glass-fabric reinforced plastic film 120 described above can be manufactured through a process of impregnating the glass fabrics with transparent resin and pressing and hardening the transparent resin.

When the transparent glass-fabric reinforced plastic film 120 is bonded to the glass 110, and then impact is applied to the glass, the glass-fabric reinforced plastic film at the rear surface supports the glass and functions as an impact absorbing support layer, thereby reducing impact deformation of the glass and absorbing the impact so as to improve the impact resistance of the glass.

Here, a difference in refractive index between the glass fabric and the transparent plastic resin can be 0.05 or smaller.

In general, a glass-fabric reinforced plastic film containing glass fabrics as fillers in a transparent plastic film is not transparent. Hence, the transparent glass-fabric reinforced plastic film of the invention is manufactured of plastic resin which has the refractive index equal to or approximate to the refractive index of glass fabrics, and more specifically, the transparent plastic having a refractive index with a difference of 0.05 or smaller from that of the glass fabrics. In addition, the transparent glass-fabric reinforced plastic film manufactured by minimizing a difference in optical properties between the glass fabrics and the transparent plastic substrate is transparent by inhibiting light scattering at the glass fabrics in the transparent glass-fabric reinforced plastic film.

When the difference in refractive index between the glass fabrics and the transparent plastic substrate exceeds 0.05, the difference is not desirable in that light transmittance can be reduced, and thus a pattern of the glass fabrics is visible. Hence, it is desirable that the glass fabrics and the transparent plastic substrate have no difference in refractive index to be transparent such that the pattern of the glass fabrics is not visible.

The transparent plastic resin used in the transparent glass-fabric reinforced plastic film 120 can include any one selected from the group consisting of siloxane resin, silicone resin, acrylic resin, epoxy resin, styrene-based resin, styrene-acrylonitrile resin, polycarbonate-based resin, polyester resin, polyurethane-based resin, acrylonitrile-butadiene-styrene-based resin, and a compound thereof; however, the transparent plastic resin is not limited thereto, and any known resin which can be used as a material for a transparent plastic film can be used without limitation.

The transparent glass-fabric reinforced plastic film 120 of the invention having an above-described configuration can have optical transmittance of 80% or higher.

The transparent glass-fabric reinforced plastic film has high transmittance as described above, and thereby a cover window having a transparent characteristic which can be applied to a display can be provided.

The transparent glass-fabric reinforced plastic film 120 of the invention having the above-described configuration can have an elastic modulus of 5 GPa or higher and a thermal expansion coefficient of 20 ppm/° C. or smaller.

Use of the transparent glass-fabric reinforced plastic film 120 of the invention having characteristics described above enables a cover window having improved durability to be provided.

According to the embodiment of the invention, configurational characteristics described above have an effect of providing the flexible composite cover window in which the glass-fabric reinforced plastic film protects the glass against impact applied to the glass or offsets the impact, and thereby the pen-drop impact resistance is improved and the strength and flexibility are secured.

In addition, according to the embodiment of the invention, the configurational characteristics described above have an effect of providing a flexible composite cover window having foldability and bendability, along with good optical properties, while a surface of the flexible composite cover window maintains unique texture and strength of the glass and scratch resistance, thus enhancing the visibility of a display and having an effect of having high impact resistance.

A flexible composite cover window according to still another embodiment of the invention is described.

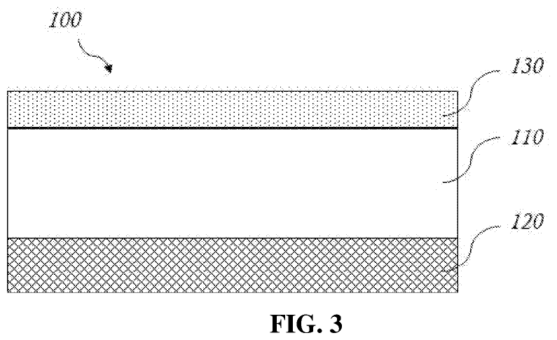

FIG. 3 is a schematic view illustrating a schematic cross-section of the flexible composite cover window including the transparent glass-fabric reinforced plastic film 120, which is bonded to the rear surface of the glass, and further including a hard coating layer on the front surface of the glass, according to the other embodiment of the invention.

With reference to FIG. 3, the flexible composite cover window according to the other embodiment of the invention can include the transparent glass-fabric reinforced plastic film 120 positioned on the rear surface of the glass 110 and a hard coating layer 130 positioned on the front surface of the glass 110.

Addition of a hard coating layer or a separate protective film to the front surface of the glass as described above enables the glass to be protected against direct pen-drop impact such that the impact resistance of the cover window 100 can be further improved.

Here, the hard coating layer 130 can be a transparent plastic resin protective coating or an additional transparent glass-fabric reinforced plastic film. Here, the transparent plastic resin protective coating or the additional transparent glass-fabric reinforced plastic film can have foldable or bendable characteristics.

According to the embodiment of the invention, the configurational characteristics described above have the effect of providing the flexible composite cover window which is protected by the added hard coating layer against the direct pen-drop impact to further improve the impact resistance.

A manufacturing method of a flexible composite cover window according to still another embodiment of the invention is described.

The manufacturing method of a flexible composite cover window of the invention can include: preparing glass; and forming a transparent glass-fabric reinforced plastic film on the prepared glass.

In the forming of the transparent glass-fabric reinforced plastic film on the glass, the transparent glass-fabric reinforced plastic film can be formed by adhering to the glass by using an adhesive.

Alternatively, in the forming of the transparent glass-fabric reinforced plastic film on the glass, in order to avoid using an adhesive having a soft property, the transparent glass-fabric reinforced plastic film can adhere to the glass by putting glass fabric on the glass, applying transparent plastic resin thereon, then, directly impregnating the glass fabric with the transparent plastic resin, and press-hardening the transparent plastic resin.

As described above, an adhesive or a coating layer can be present between the glass and the glass-fabric reinforced plastic film. Here, as the thickness of the adhesive or the coating layer is minimized, it is advantageous in having high foldability and bendability.

According to the embodiment of the invention, configurational characteristics described above have an effect of providing the manufacturing method of a flexible composite cover window of which the impact resistance is improved and the strength and flexibility are secured.

A display device according to still another embodiment of the invention is described.

According to the other embodiment of the invention, the display device of the invention can include the flexible composite cover window according to the embodiment of the invention.

The description of the flexible composite cover window is the same as the description in the embodiments, and thus, is omitted.

The display device of the invention can be disposed on a film including a touch circuit and a display circuit when the flexible composite cover window according to the embodiment of the invention is applied to the display device; however, the display device is not limited thereto.

According to the embodiment of the invention, configurational characteristics described above have an effect of providing the display device which can be used as a touch screen and in which a display panel is protected by forming a cover window, which has reliable folding and bending characteristics and reliable flexibility and durability, on a front surface of a display.

Hereinafter, the invention will be described in more detail with manufacturing examples, comparative examples, and experimental examples. However, the invention is not limited to the following manufacturing examples and experimental examples.

### Example 1

### Manufacture 1 of Flexible Composite Cover Window

A flexible composite cover window having the same cross-section as that in FIG. 1 was manufactured to have a transparent glass-fabric reinforced plastic film which was directly bonded to foldable and bendable glass by putting glass fabric (Nittobo, 1037) having a thickness of 0.025 mm on each rear surface of pieces of foldable and bendable glass having thicknesses of 0.03 mm and 0.05 mm, respectively, impregnating the glass fabric with transparent siloxane resin (ClearFRP manufactured by Solip Tech Co., Ltd.) which is adjusted to have the same refractive index as that of the glass fabric, and press-hardening the siloxane resin.

### Example 2

### Manufacture 2 of Flexible Composite Cover Window

A flexible composite cover window having the same cross-section as that in FIG. 3 was manufactured to include a transparent glass-fabric reinforced plastic film that was directly bonded to foldable and bendable glass by putting glass fabric (Nittobo, 1037) having a thickness of 0.025 mm on each rear surface of pieces of foldable and bendable glass having thicknesses of 0.03 mm and 0.05 mm, respectively, impregnating the glass fabric with transparent siloxane resin (ClearFRP manufactured by Solip Tech Co., Ltd.) which is adjusted to have the same refractive index as that of the glass fabric, and press-hardening the siloxane resin, and to include a protective coating having a thickness of 0.01 mm that was applied to a front surface of glass by applying transparent hard coating resin (Flex9H manufactured by Solip Tech Co., Ltd.) thereon.

### Example 3

### Manufacture 3 of Flexible Composite Cover Window

A flexible composite cover window having the same cross-section as that in FIG. 2 was manufactured to include a transparent glass-fabric reinforced plastic film that was directly bonded to foldable and bendable glass by putting glass fabric (Nittobo, 1037) having a thickness of 0.025 mm on each rear surface of pieces of foldable and bendable glass having thicknesses of 0.03 mm and 0.05 mm, respectively, impregnating the glass fabric with transparent siloxane resin (ClearFRP manufactured by Solip Tech Co., Ltd.) which is adjusted to have the same refractive index as that of the glass fabric, and press-hardening the siloxane resin, and to include another transparent glass-fabric reinforced plastic film that was directly bonded to each front surface thereof in the same manner.

### Comparative Example 1

### Manufacture of Protective-Coating Flexible Cover Window

A protective-coating flexible cover window was manufactured to have a one-surface protective coating having a thickness of 0.03 mm equal to the thickness of the glass-fabric reinforced plastic film by applying transparent hard coating resin (Flex9H manufactured by Solip Tech Co., Ltd.) on each rear surface of pieces of foldable and bendable glass having thicknesses of 0.03 mm and 0.05 mm, respectively.

### Comparative Example 2

### Manufacture of Protective-Coating Flexible Cover Window

A protective-coating flexible cover window was manufactured to have a both-surface protective coating having a thickness of 0.03 mm equal to the thickness of the glass-fabric reinforced plastic film by applying transparent hard coating resin (Flex9H manufactured by Solip Tech Co., Ltd.) on the front surface and the rear surface of pieces of foldable and bendable glass having thicknesses of 0.03 mm and 0.05 mm, respectively.

### Experimental Example 1

### Performance Evaluation Test

1. Folding Test In order to evaluate folding characteristics of the flexible cover windows obtained in the examples and the comparative examples, a folding radius of the flexible cover window which endured 100,000 times of folding is measured using a tension-free U-shape folding tester (YUASA System Co., Ltd.), and results thereof are shown in Table 1. Here, the results show that the smaller the folding radius, the better the folding characteristics.

2. Pen-Drop Test

In order to evaluate pen-drop impact resistance characteristics of the flexible cover windows obtained in the examples and the comparative examples, the flexible cover window was adhered to a glass substrate using an adhesive (3M OCA 8146-1) having a thickness of 0.025 mm, then, a maximum height was measured by dropping a common ballpoint pen (BIC Crystal Fine 0.7 mm) to the flexible cover window from a certain height, and results thereof are shown in Table.

TABLE 1

| | | | | | | | Comparative | | Comparative | |
|---|---|---|---|---|---|---|---|---|---|---|
| | Example 1 | | Example 2 | | Example 3 | | Example 1 | | Example 2 | |
| Glass | 0.03 | 0.05 | 0.03 | 0.05 | 0.03 | 0.05 | 0.03 | 0.05 | 0.03 | 0.05 |
| thickness | | | | | | | | | | |
| (mm) | | | | | | | | | | |
| Folding | 2.0 | 3.0 | 3.0 | 4.0 | 3.5 | 4.5 | 2.5 | 3.5 | 4.5 | 6.0 |
| radius | | | | | | | | | | |
| (mm) | | | | | | | | | | |
| Pen-drop | 20 | 24 | 25 | 29 | 32 | 36 | 6 | 9 | 11 | 15 |
| impact | | | | | | | | | | |
| resistance | | | | | | | | | | |
| height | | | | | | | | | | |
| (mm) | | | | | | | | | | |

As known in Table 1, the folding radius increases in proportion to the thickness of the flexible composite cover window of the examples and the protective-coating cover window of the comparative examples. The folding radius is smaller in Examples 1 and 3 in which the glass-fabric reinforced plastic film is used than in Comparative Examples 1 and 2 in which the coating is applied to an impact offsetting layer at the rear surface or the protective layer at the front surface of the glass, the impact offsetting layer and the protective layer having the same thickness. This enables to know that use of the glass-fabric reinforced plastic film as the invention is further advantageous. In addition, the pen-drop impact resistance height in Example 1, in which the transparent glass-fabric reinforced plastic film is used as an impact absorbing layer at the rear surface of the glass, is higher than that in Comparative Example 1 in which the hard coating is used. This also indicates an effect of use of the transparent glass-fabric reinforced plastic film. In addition, the pen-drop impact resistance height in Example 2, in which the hard coating is used as the protective layer at the front surface of the glass and in Comparative Example 3, in which the additional glass-fabric reinforced plastic film adheres to the glass, is higher than that in Example 1 and Comparative Example 1 in which the protective layer is not provided. Besides, the pen-drop impact resistance height in Example 3, in which the transparent glass-fabric reinforced plastic film is adhered to the glass, is higher than that in Example 2, in which the hard coating is applied as the protective layer. This can indicate that the glass-fabric reinforced plastic film is highly effective as the protective layer. Hence, an effect of the glass-fabric reinforced plastic film as the impact absorbing layer or the protective layer of the glass was verified to be much higher than that of the coating.

The embodiments of the invention have effects of providing a flexible composite cover window, a manufacturing method thereof, and a display device including the same, the flexible composite cover window having improved pen-drop impact resistance, high strength, and good foldability and flexibility by bonding a glass-fabric reinforced plastic film to the rear surface and/or the front surface of glass such that the glass-fabric reinforced plastic film protects the glass against impact applied to the glass or offsets the impact, in order to improve impact resistance of a thin glass cover window which is foldable or bendable.

In addition, the embodiment of the invention has effects of providing a flexible composite cover window, a manufacturing method thereof, and a display device including the same, the flexible composite cover window having foldability and bendability, along with good optical properties, while a surface of the flexible composite cover window maintains unique texture and strength of the glass and scratch resistance, and thus enhancing visibility of a display and having an effect of having high impact resistance.

Effects of the invention are to be construed not to be limited to the above-mentioned effects but to include any effect that can be derived from configurations of the invention described in the detailed description of the preferred embodiment and claims of the invention.

The above description of the invention is provided as an example, and a person of ordinary skill in the art to which the invention pertains can understand that it is possible to easily modify the invention to another embodiment without changing the technical idea or essential feature of the invention. Therefore, the embodiments described above have to be understood as exemplary embodiments in every aspect and not as examples to limit the invention. For example, each configurational element described as a single unit can be realized in a distributed manner. Similarly, the configurational element described in a distributed manner can be realized in a combined manner.

The scope of the invention has to be represented by the claims to be described below, and the meaning and the scope of the claims and every modification or modified embodiment derived from an equivalent concept of the claims have to be construed to be included in the scope of the invention.

What is claimed is:

1. A flexible composite cover window comprising:
a glass; and
a transparent glass-fabric reinforced plastic film positioned on the glass.

2. The flexible composite cover window according to claim 1,
wherein the transparent glass-fabric reinforced plastic film is bonded to a front surface, a rear surface, or both the front surface and the rear surface of the glass.

3. The flexible composite cover window according to claim 1,
wherein the glass has a thickness of 0.1 mm or smaller to be foldable or bendable.

4. The flexible composite cover window according to claim 1,
wherein the transparent glass-fabric reinforced plastic film is a film having glass fabric in a transparent plastic substrate, and a difference in refractive index between the glass fabric and the transparent plastic substrate is 0.05 or smaller.

5. The flexible composite cover window according to claim 4,
wherein the transparent plastic substrate contains a resin composition including any one selected from a group consisting of acrylic resin, epoxy resin, silicone resin, siloxane resin, styrene-based resin, styrene-acrylonitrile resin, polycarbonate-based resin, polyester resin, polyurethane-based resin, acrylonitrile-butadiene-styrene-based resin, and a compound thereof.

6. The flexible composite cover window according to claim 1,
wherein the transparent glass-fabric reinforced plastic film has a thickness of 0.1 mm or smaller.

7. The flexible composite cover window according to claim 1,
wherein the transparent glass-fabric reinforced plastic film has optical transmittance of 80% or higher.

8. The flexible composite cover window according to claim 1, further comprising:
an adhesive layer or a coating layer positioned between the glass and the transparent glass-fabric reinforced plastic film.

9. The flexible composite cover window according to claim 1,
wherein the transparent glass-fabric reinforced plastic film is positioned on a rear surface of the glass, and
wherein the flexible composite cover window further includes a hard coating layer positioned on a front surface of the glass.

10. A manufacturing method of a flexible composite cover window, comprising:
preparing a glass; and
forming a transparent glass-fabric reinforced plastic film on the prepared glass.

11. The manufacturing method according to claim 10,
wherein, in forming of the transparent glass-fabric reinforced plastic film on the glass, the transparent glass-fabric reinforced plastic film is formed by adhering to the glass.

12. The manufacturing method according to claim 10,
wherein, in forming of the transparent glass-fabric reinforced plastic film on the glass, the transparent glass-fabric reinforced plastic film adheres to the glass by putting glass fabric on the glass and directly impregnating the glass fabric with plastic resin and press-hardening the plastic resin.

13. A display device comprising:
the flexible composite cover window according to claim 1.
